(19) United States
(12) Patent Application Publication
(10) Pub. No.: US 2018/0199431 A1
(43) Pub. Date: Jul. 12, 2018

(54) CIRCUIT SUPPORT FOR AN ELECTRONIC CIRCUIT AND METHOD FOR MANUFACTURING A CIRCUIT SUPPORT OF SAID TYPE

(71) Applicant: OSRAM GmbH, Munich (DE)

(72) Inventors: Michael Schoewel, Wittislingen (DE); Peter Helbig, Sontheim an der Brenz (DE); Jozsef Szekely, Gannertshofen (DE); Sven Seifritz, Herbrechtingen (DE)

(21) Appl. No.: 15/740,378

(22) PCT Filed: May 20, 2016
(86) PCT No.: PCT/EP2016/061441

§ 371 Date: Dec. 28, 2017

(30) Foreign Application Priority Data
Jun. 30, 2015 (DE) 10 2015 212 177.1

(51) Int. Cl. H05K 1/02; H05K 1/18; H05K 3/00; H05K 3/20; H05K 13/00; F21S 41/19

(52) U.S. Cl. CPC H05K 1/0296; H05K 1/181; H05K 3/0014; H05K 3/202; F21V 21/00; F21S 41/19; H05K 2203/166; H05K 2201/10318; H05K 2201/10113; H05K 13/0069

(57) ABSTRACT

Various embodiments relate to a circuit support for an electronic circuit. The circuit support may include at least one conductor track, and an insulating matrix that is injection-molded over the at least one conductor path in such a way as to leave open at least a first region for connecting at least one electronic component of the electronic circuit. The circuit support may include at least one fastening aid that is formed from the material for the insulating matrix and/or from the material of the at least one conductor.

### RELATED APPLICATIONS

The present application is a national stage entry according to 35 U.S.C. § 371 of PCT application No.: PCT/EP2016/061441 filed on May 20, 2016, which claims priority from German application No.: 10 2015 212 177.1 filed on Jun. 30, 2015, and is incorporated herein by reference in its entirety.

### TECHNICAL FIELD

Various embodiments generally relate to a circuit support for an electronic circuit, said circuit support including at least one conductor track and an insulating matrix that is injection-molded over the at least one conductor track in such a way as to leave open at least a first region for connecting at least one electronic component of the electronic circuit. Various embodiments further relate to a method for producing a circuit support for an electronic circuit, wherein the circuit support includes at least one conductor track and an insulating matrix that is injection-molded over the at least one conductor track in such a way as to leave open at least a first region for connecting at least one electronic component of the electronic circuit.

The present disclosure is concerned with the problem of fastening a circuit support of this type itself in a suitable or a desired manner, in particular also with the problem of being able to align said circuit support in the desired manner during the fastening procedure. The present disclosure is further concerned with the problem of fastening components, in particular electronic components onto a circuit support of this type.

### BACKGROUND

It is known from the related art by way of example to solder, adhere, weld, laminate or secure fastening aids to a circuit support of this type. The additional method steps and components that these methods require result in an additional production outlay that is reflected in a comparatively long period of time required and also additional costs.

### SUMMARY

Various embodiments provide a generic circuit support or a generic method for producing a circuit support in such a manner that fastening aids for the circuit support itself and/or for components that are to be arranged on the circuit support can be provided in a most cost-effective manner possible whilst at the same time reducing the number of product steps in comparison to the approach known in the related art.

The present disclosure is based on the knowledge that the object mentioned above with regard to the circuit support in accordance with the present disclosure can be achieved in an optimum manner if the circuit support includes at least one fastening aid that is formed from the material for the insulating matrix and/or from the material of the at least one conductor track.

Consequently, it is fundamentally possible to produce the required fastening aid at the same time as producing the at least one conductor track and/or at the same time as producing the at least one insulating matrix. In other words, the procedure of producing fastening aids of this type is integrated in accordance with the present disclosure into the procedure of producing the conductor track and/or the insulating matrix. It is possible in this manner to considerably reduce the number of production steps in the case of a circuit support in accordance with the present disclosure in comparison to known circuit supports which results both in a reduction in the production time and also in the production costs.

Accordingly, the production steps for the fastening aids of a circuit support in accordance with the present disclosure can be performed in a stamping, bending and/or embossing process so as to produce the actual circuit supports in the conventional manner if the fastening aid is formed from the material of the at least one conductor track or said production steps are taken into consideration afterwards during the injection-molding process, in other words when producing the insulating matrix. Furthermore, the approach in accordance with the present disclosure results in a very high degree of manufacturing accuracy of the fastening aids that are being produced since the fastening aids—in contrast to the procedure in the related art—are produced in accordance with the present disclosure using a tool-based process and thus said fastening aids are subjected to a reproducible process.

One advantageous embodiment of a circuit support in accordance with the present disclosure is characterized by virtue of the fact that the at least one conductor track is configured as a leadframe, wherein the at least one fastening aid is formed from the material for the leadframe and represents one element of the following group:
a pin that is stamped as one and bent on the leadframe
   for a mechanical function, in particular for fastening, centering, as a clamping element or as a gripping aid, and/or
   for an electrical function, in particular as a contact lug or as a test site;
a latching lug that is stamped or embossed on the leadframe;
an alignment pin or a centering pin that is drawn on the leadframe;
a fiducial marker that is embossed or stamped on the leadframe;
a gripping aid that is stamped and bent on the leadframe;
a receiving hole that is stamped into the leadframe;
spring contacts that are stamped and bent into the leadframe so as to receive and make contact with an electrical component.

It has hitherto only been known in the related art in order to realize additional functions to form or fold metal strips from the leadframe material and to use said metal strips as cooling bodies. However, it has hitherto not been known to produce fastening aids from the material of the leadframes, in particular in the manner as described in the above mentioned summary.

In accordance with a further preferred embodiment, the at least one fastening aid is formed from the material for the insulating matrix and represents one element from the following group:
a locating pin that is produced by injection molding;
a fiducial marker that is produced by injection molding;
a gripping aid that is produced by injection molding;
a snap-in hook that is produced by injection molding.

It is usual to use a synthetic material to produce the insulating matrix and to apply said synthetic material in a thickness of 0.2 to 0.3 mm to at least the sites on the conductor track that are to be insulated. In accordance with the mentioned advantageous embodiment, henceforth at least one fastening aid is produced from the same material at the same time during the injection molding process for producing the insulating matrix.

Various embodiments still further relate to a light source, in particular a light source for a vehicle illumination arrangement, preferably a vehicle headlight, having a circuit support in accordance with the present disclosure.

The preferred embodiments that have been presented with regard to the circuit support in accordance with the present disclosure and the advantages of said embodiments also apply for the method in accordance with the present disclosure for producing a circuit support. In the case of said method, at least one fastening aid is formed from the material for the insulating matrix and/or from the material of the at least one conducting track. The term ‘to form’ is understood in this case to mean a stamping, bending or milling process when said fastening aid is formed from the material of the conductor track and an injection molding process when said fastening aid is formed from the material for the insulating matrix.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIGS. 1A and 1B illustrate schematic views of pins that are stamped as one and bent on a leadframe;

FIGS. 2A and 2B illustrate schematic views of latching lugs that are stamped or embossed on a leadframe;

FIGS. 3A-3C illustrate schematic views of centering pins or alignment pins and gripping aids that are drawn on a leadframe;

FIGS. 4A and 4B illustrate schematic views of fiducial markers that are embossed or stamped on a leadframe;

FIGS. 5A and 5B illustrate schematic views of receiving holes that are stamped in a highly accurate manner in a leadframe;

FIGS. 6A and 6B illustrate schematic views of spring contacts that are stamped and bent in a leadframe, said spring contacts being provided so as to receive and make contact with a component; and

FIG. 7 illustrates a schematic view of a cross-section through a first embodiment of a circuit support in accordance with the present disclosure.

### DETAILED DESCRIPTION

The same reference numerals are used in the descriptions hereinunder for like and like-functioning components. Said reference numerals are only inserted once for the sake of clarity.

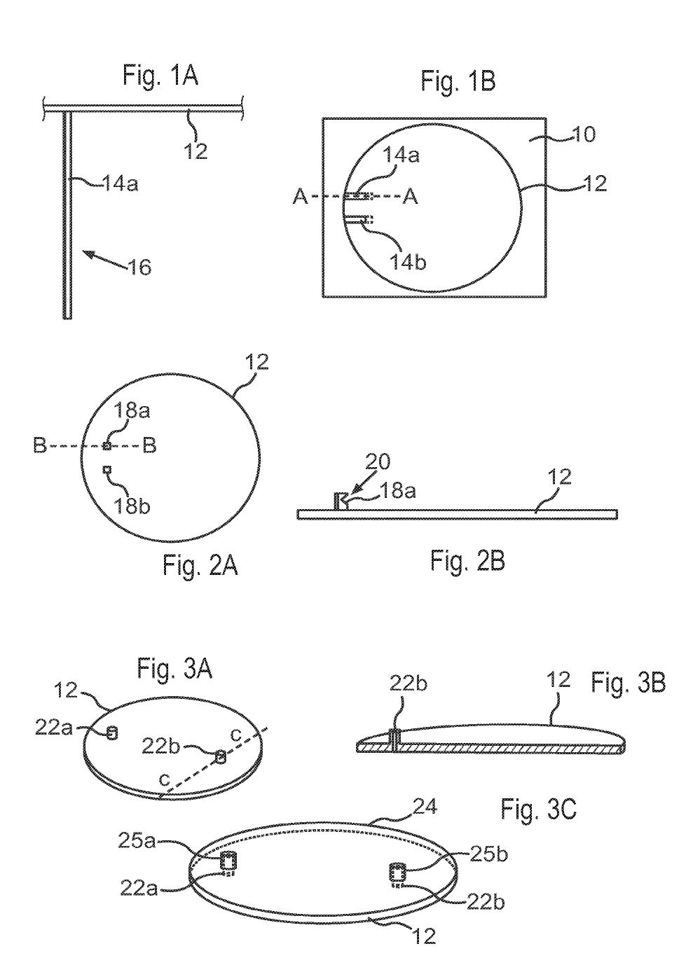

FIG. 1B illustrates initially a rectangular section 10 of a metal strip, wherein a circle 12 is stamped out in a first processing step so as to produce a leadframe. Two strips 14a, 14b are stamped and subsequently bent over simultaneously so as to produce the pins. The illustration in FIG. 1A illustrates an enlarged view along the section line A-A of FIG. 1B. A pin 16 of this type can assume a mechanical function, in particular for the fastening process and for the centering process, as a clamping element or as a gripping aid. However, it can also assume an electrical function, in particular as a contact lug or as a test site.

FIG. 2A illustrates a plan view of two latching lugs 18a, 18b that are produced on the leadframe by stamping and embossing the leadframe. A rectangular opening is stamped into the leadframe 12 in a first step and subsequently a synthetic material is pressed through the opening from below. The notch 20 of the corresponding latching lug 18a, 18b is produced in a subsequent embossing step. FIG. 2B illustrates an enlarged sectional view along the section line B-B of FIG. 2A. It is possible to realize a desired spring effect by suitably selecting the synthetic material that is produced for the latching lugs.

Accordingly, it is possible using the two latching lugs 18a, 18b that are illustrated in FIG. 2A to secure a component in two directions, in that said component is pushed in between the two latching lugs 18a, 18b. The component can be secured in all directions on the leadframe 12 by means of four latching lugs 18 of this type.

FIG. 3A illustrates by way of example two centering pins or alignment pins 22a, 22b that are drawn on the leadframe 12. FIG. 3B illustrates an enlarged cross-sectional view along the section line C-C from FIG. 3A. FIG. 3C illustrates a schematic view of a component 24 having two hollow pins 25a, 25b that are bent over the centering pins or alignment pins 22a, 22b in order to position the component 24 with respect to the leadframe 12.

The centering pins or alignment pins 22a, 22b can also be used as gripping aids. As an alternative, by way of example gripping aids can be produced on the outer surface of the leadframe 12 during the stamping process, as described in connection with FIG. 1B.

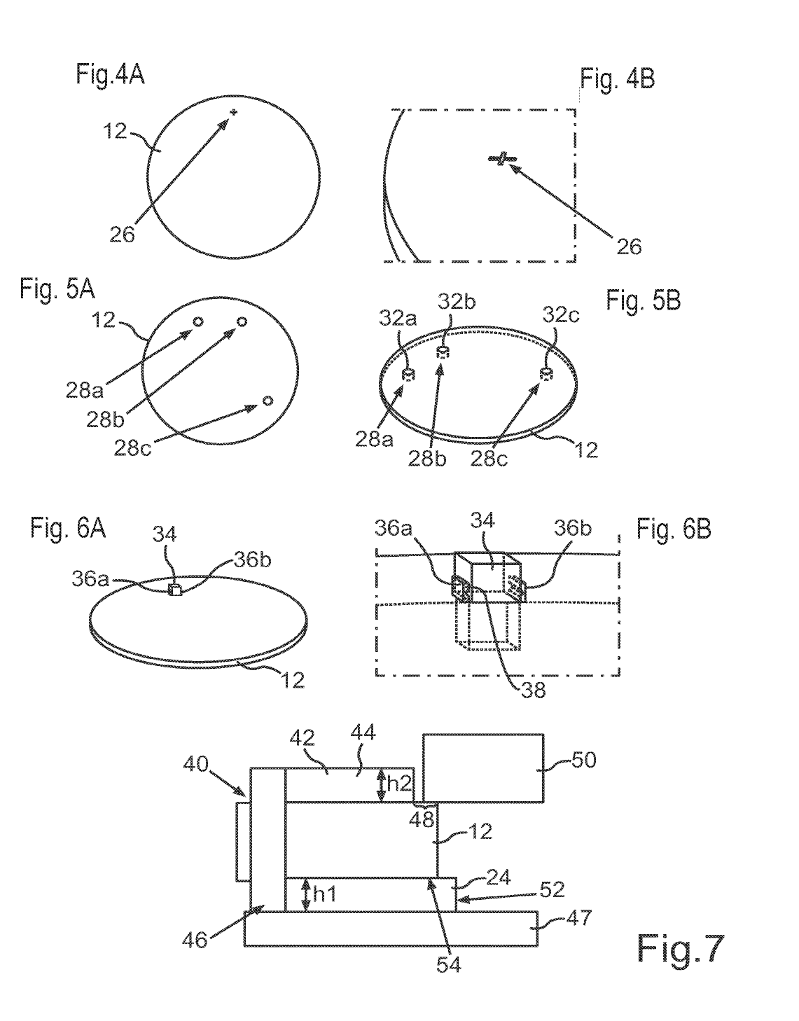

FIG. 4A illustrates a fiducial marker 26 that is embossed or stamped on the leadframe 12. FIG. 4B illustrates the view of FIG. 4A in an enlarged format.

FIG. 5A illustrates receiving holes 28a, 28b, 28c that are stamped in a highly precise manner on the leadframe 12. The view in FIG. 5B illustrates how a schematically illustrated component 30 having the alignment pins 32a, 32b, 32c is positioned on the leadframe 12, in that the alignment pins 32a to 32c are inserted into the receiving holes 28a to 28c.

FIG. 6A illustrates a component 34 that is inserted between and makes contact with spring contacts 36a, 36b that are stamped and bent in the leadframe 12. FIG. 6B illustrates the arrangement in an enlarged view. In the illustrated view, the component 34 is inserted from below in the image display between the spring contacts 36a, 36b. It is possible to position the component 34 in a precise and desired manner with respect to its height by means of a correspondingly configured profiling 38 of the spring contacts 36a, 36b and a corresponding profiling of the component 34. In the illustration shown in FIGS. 6A and 6B, the component 34 can be by way of example a locating pin that is produced from the material of the insulating matrix by injection molding.

The fastening aids 14, 18, 22, 26, 28, 36 in the embodiments illustrated in FIGS. 1 to 6 are shaped from the material of the leadframe 12. As is obvious to the person skilled in the art, said fastening aids, in particular the gripping aids 16, fiducial markers 26 and also centering pins and alignment pins 22, can also be produced by injection molding from the material that is used for the insulating matric of the circuit support.

The leadframe 12 is processed using stamping technology in multiple steps. The starting material, in particular the starting metal strips, is/are processed in one step only until the material no longer distorts or becomes wavy. The processing is preferably performed using a progressive tool. In so doing, the starting material passes through multiple processing steps on the production belt. It is possible in this manner to use a stamping press that requires comparatively less power.

FIG. 7 illustrates a circuit support in accordance with the present disclosure for an electronic circuit. Said circuit support includes a conductor track 12 that is configured in particular as a leadframe. Through-going openings and/or gaps 40 are provided in the conductor track 12 and an insulating material 42 is injection-molded around the conductor track 12 so as to form an insulating matrix 44 and in so doing form a protrusion 46 in particular also on the side of the conductor track 12 that can be coupled to a cooling body 47. During the procedure of applying the insulating material by injection molding, the regions 48 that are provided for assembling the electronic components 50, and also the region 52 on the lower face 54 of the conductor track 12 are omitted. This is achieved by means of a corresponding configuration of the injection-molding tool.

A multiplicity of protrusions 46 of this type that act as spacers are produced as a result of corresponding through-going openings and/or gaps 40 being provided along the conductor track 12, in other words in the direction perpendicular to the plane of the drawing. If a cooling body 47 is placed on the multiplicity of the protrusions 46, the region 52 is produced that has a height h1 that amounts to between 20 μm and 200 μm. In contrast, the height h2 of the matrix material 42 amounts to between 0.2 mm and 0.4 mm. The region 52 is subsequently filled with a second insulating material that can represent in particular a heat-conducting paste or a heat-conducting adhesive.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A circuit support for an electronic circuit, said circuit support comprising:
at least one conductor track; and
an insulating matrix that is injection-molded over the at least one conductor path in such a way as to leave open at least a first region for connecting at least one electronic component of the electronic circuit;
wherein the circuit support comprises at least one fastening aid that is formed from the material for the insulating matrix and/or from the material of the at least one conductor.

2. The circuit support as claimed in claim 1,
wherein the at least one conductor track is configured as a leadframe, wherein the at least one fastening aid is formed from the material for the leadframe and represents one element from the following group:
a pin that is stamped as one and bent on the leadframe
for a mechanical function, as a clamping element or as a gripping aid, and/or
for an electrical function;
a latching lug that is stamped or embossed on the leadframe;
an alignment pin or a centering pin that is drawn on the leadframe;
a fiducial marker that is embossed or stamped on the leadframe;
a gripping aid that is stamped and bent on the leadframe;
a receiving hole that is stamped in the leadframe;
spring contacts that are stamped and bent into the leadframe so as to receive and make contact with an electrical component.

3. The circuit support as claimed in claim 1,
wherein the at least one fastening aid is formed from the material for the insulating matrix and represents one element from the following group:
a locating pin that is produced by injection molding;
a fiducial marker is produced by injection molding;
a gripping aid that is produced by injection molding;
a snap-in hook that is produced by injection molding.

4. A method for producing a circuit support for an electronic circuit, wherein the circuit support comprises at least one conductor track and an insulating matrix that is injection-molded over the at least one conductor track in such a way as to leave open at least a first region for connecting at least one electronic component of the electronic circuit;
the method comprising:
forming at least one fastening aid from the material for the insulating matrix and/or from the material of the at least one conductor track.

5. A light source, comprising a circuit support said circuit support comprising:
at least one conductor track; and
an insulating matrix that is injection-molded over the at least one conductor path in such a way as to leave open at least a first region for connecting at least one electronic component of the electronic circuit
wherein the circuit support comprises at least one fastening aid that is formed from the material for the insulating matrix and/or from the material of the at least one conductor.

6. The circuit support as claimed in claim 2,
wherein the pin is for the fastening process or for the centering process.

7. The circuit support as claimed in claim 2,
wherein the pin is for an electrical function as a contact lug or as a test site.

8. The light source according to claim 5,
wherein the light source is used for a vehicle headlight.
